(19) United States
(12) Patent Application Publication
(10) Pub. No.: US 2025/0109011 A1
(43) Pub. Date: Apr. 3, 2025

(54) INTEGRATED SENSOR DEVICE

(71) Applicant: Infineon Technologies AG, Neubiberg (DE)

(72) Inventors: Horst THEUSS, Wenzenbach (DE); Rainer Markus SCHALLER, Aichen (DE)

(21) Appl. No.: 18/888,968

(22) Filed: Sep. 18, 2024

(30) Foreign Application Priority Data
Sep. 28, 2023 (DE) 102023126506.7

(51) Int. Cl. B81B 3/00; B81B 7/00; B81C 1/00; G01L 19/06

(52) U.S. Cl. CPC B81B 3/0072; B81B 7/0074; B81C 1/0023; B81C 1/00666; G01L 19/0627; B81B 2201/0214; B81B 2201/0257; B81B 2201/0264; B81B 2207/07; B81C 2203/0792

(57) ABSTRACT

A description is given of a sensor device and a method for producing same. According to one example implementation, the sensor device includes a chip carrier, a semiconductor chip mounted on the chip carrier, and electrical connections between connection pads of the semiconductor chip and corresponding connection pads of the chip carrier. The sensor device further includes a sensor chip arranged on the semiconductor chip and having a sensor element. The sensor chip has trenches that mechanically decouple the sensor element from the rest of the sensor chip. The chip package forms a mold compound that at least partially encapsulates the semiconductor chip and the electrical connections and has an opening in the region of the sensor element so that the sensor element can interact with a medium surrounding the sensor device. The mold compound covers the semiconductor chip except for the sensor chip.

### CROSS-REFERENCE TO RELATED APPLICATION

This application claims priority to Germany Patent Application No. 102023126506.7 filed on Sep. 28, 2023, the content of which is incorporated by reference herein in its entirety.

### TECHNICAL FIELD

The present invention relates to the field of integrated sensors.

### BACKGROUND

Many sensor devices are constructed nowadays as what is known as system-in-package (SiP), that is to say they have one or more chips in a chip package, in which chips both the sensor element and further electronic circuits are integrated. Many integrated sensors are so-called smart sensors (also referred to as intelligent sensors) that contain not only the sensor element (which is sensitive to a specific environmental parameter such as for example pressure, temperature, carbon monoxide, or the like) but also further electronic circuits that for example can process (for example amplify, digitize, filter, etc.) the sensor signal and can optionally communicate with other electronic units.

Various concepts for the production of integrated sensors are known per se. One example is micromechanical structures integrated in silicon, so-called MEMS (microelectromechanical systems). Another example is sensor elements produced using SOI (silicon-on-insulator) or SOS (silicon-on-sapphire) technology and containing for example piezoresistive elements. SiC (silicon carbide) based technologies SiCOI (SiC-on-insulator) are also known for the production of integrated sensor elements for pressure measurement. Hereinafter, sensor elements integrated in chips are referred to as sensor chips.

MEMS sensors can be configured for example for a multiplicity of sensor applications. There are MEMS sensors for measuring pressure (in a gas atmosphere), for measuring air quality, for detecting various chemical elements, and much more. Properties of the medium surrounding the sensor are referred to hereinafter as environmental parameters. In order to be able to measure an environmental parameter, the sensor element must be physically in contact with the medium surrounding it. That is to say that, in contrast to other integrated circuits (ICs), the sensor chip must not be completely encapsulated in a potting compound, but rather has to contain an opening that allows physical contact between the sensor element and the surrounding medium (usually a gas). The packaging of an integrated sensor device thus has to satisfy different requirements than the packaging of conventional semiconductor chips. In particular, in the case of MEMS, there is the risk of introducing mechanical stresses into the sensor chip, which can negatively affect the performance of the sensor chip.

The inventors have addressed the problem of improving the production of integrated sensor devices, in particular the packaging.

### SUMMARY

The aforementioned problem is solved using the sensor device as claimed in patent claim 1 and also using the method as claimed in patent claim 12. Various implementations and developments are the subject of the dependent claims.

A description is given hereinafter of a sensor device and a method for producing same. According to one example implementation, the sensor device includes a chip carrier, a semiconductor chip mounted on the chip carrier, and electrical connections between connection pads of the semiconductor chip and corresponding connection pads of the chip carrier. The sensor device further includes a sensor chip arranged on the semiconductor chip and having a sensor element. The sensor chip has trenches that mechanically decouple the sensor element from the rest of the sensor chip. The chip package forms a mold compound that at least partially encapsulates the semiconductor chip and the electrical connections and has an opening in the region of the sensor element so that the sensor element can interact with a medium surrounding the sensor device. The mold compound covers the semiconductor chip except for the sensor chip.

According to one example implementation, the method includes providing a wafer having a plurality of semiconductor chips and bonding a plurality of sensor chips on corresponding semiconductor chips, wherein the sensor chips each have a sensor element and trenches that mechanically decouple the sensor element from the rest of the sensor chip. The method further includes singulating the semiconductor chips with the sensor chips arranged thereon, mounting the semiconductor chips on corresponding chip carriers and then encapsulating the semiconductor chip with mold compound, wherein an opening is left free in the mold compound in the region of a sensor element of the sensor chip.

### BRIEF DESCRIPTION OF THE DRAWINGS

Example implementations are explained in more detail below with reference to figures. The illustrations are not necessarily true to scale, and the example implementations are not restricted just to the aspects that are illustrated. Rather, value is placed on illustrating the principles underlying the example implementations. With regard to the figures:

FIG. 1 illustrates one example of a conventional integrated sensor device, in which the sensor chip is arranged chip-on-chip on another semiconductor chip.

FIG. 2 illustrates one example of a novel sensor device, in which the sensor chip is arranged chip-on-chip on another semiconductor chip, wherein the two chips are electrically connected using conductor tracks (strip conductors) instead of bond wires.

FIG. 3 illustrates, in the diagrams (a) to (d), various intermediate steps in the production of the chip-on-chip arrangement from FIG. 2.

FIG. 4 illustrates, in the diagrams (a) to (d), various intermediate steps of the packaging process of the chip-on-chip arrangement from FIG. 3.

FIGS. 5 and 6 illustrate two alternative example implementations to the example from FIG. 2.

FIGS. 7-9 show further alternative example implementations.

### DETAILED DESCRIPTION

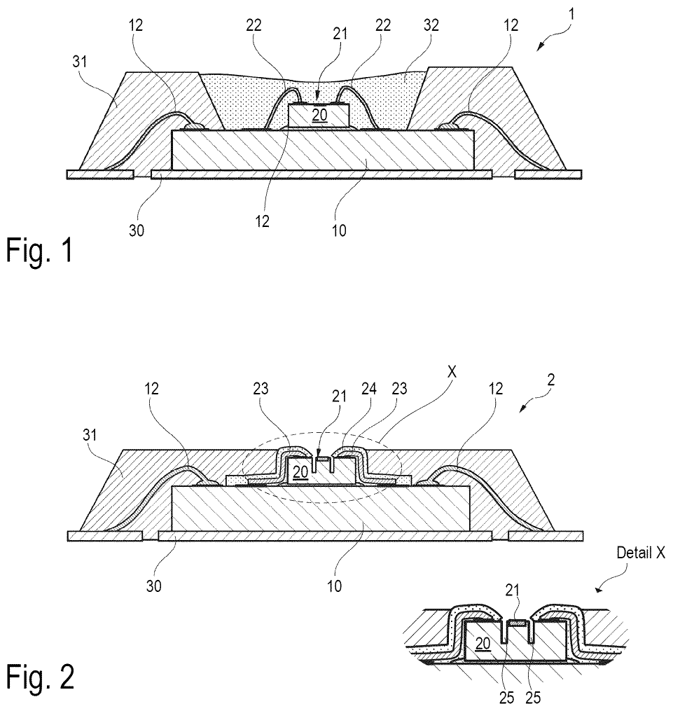

FIG. 1 illustrates one example of a conventional integrated sensor device 1, in which a sensor chip 20 is arranged chip-on-chip (CoC) on another chip 10. The chip 10 is a silicon-based semiconductor chip, for example, and is mounted on a chip carrier 30 in a manner known per se. A leadframe is usually used as a chip carrier. In specific example implementations, the chip carrier 30 can also be a multilayer substrate. Other types of chip carriers can also be used, depending on the application. The chip-on-chip technique is a technique known per se for mounting one chip directly on another chip. The chip-on-chip technique thus differs from other concepts, in which for example two or more chips are mounted next to one another on a leadframe.

The sensor chip 20 comprises a sensor element 21 at the top-side chip surface, the sensor element being configured to interact with the medium (for example a gas) surrounding the chip and thereby to measure a property (for example a physical or chemical parameter) of the medium. That is to say that the sensor element 21 generates a signal containing information about the property sought. In many applications, the sensor element 21 can be a microelectromechanical system (MEMS). MEMS are known per se as sensor elements and will therefore not be explained in detail here. For example, parameters such as the (static) pressure of the surrounding medium can be measured using MEMS. Other MEMS sensor elements can measure for example a sound pressure or the presence of a substance (for example ozone, carbon monoxide, nitrogen dioxide, ammonia, etc.) or the concentration of a substance. The underside surface of the sensor chip 20 is fixedly connected (for example using soldering or adhesive bonding) to the underlying chip 10 over the whole area. The electrical connections between the sensor chip 20 and the underlying chip 10 are produced by bond wires 22. Concepts in this regard are referred to as chip-to-chip bonding. The bond wires connect corresponding contact pads (bond pads) on the surfaces of the sensor chip 20 and of the underlying chip 10, respectively.

The semiconductor chip 10 is connected to the chip contacts (for example pins, soldering balls, etc.) of the leadframe 30 using bond wires 12. The chip 10 is encapsulated in a molding process with a potting compound 31 (mold compound). After curing, the potting compound 31 forms the chip package, which for sensor applications only partly surrounds the chip 10, however. The potting compound 31 (the chip package) has an opening (cavity) in that region in which the sensor chip 20 is situated. It should be noted that this juncture that, during production, firstly the chip 10 is mounted on the leadframe 30 (using a relatively soft adhesive layer 12), then the electrical connections between chip 10 and leadframe are produced using wire bonding (bond wires 12), and subsequently the chip package 31 with the cavity is produced. By way of example, the chip package is produced using film-assisted molding (FAM). FAM and other suitable molding processes are known per se and, therefore, will not be described in detail here.

It is only after the production of the chip package that the sensor chip 20 is mounted within the cavity on the underlying semiconductor chip 10 and electrically contacted using the bond wires 22. Depending on the application, the cavity can then remain open or be filled with a gel 32. In the case of pressure sensors, for example, the sensor element is often covered with a soft potting compound such as for example a gel (silicone gel). The soft potting compound-even after curing-must be soft enough to be able to transfer the ambient pressure to the sensor element 21. The purpose of filling the cavity with a soft potting compound is to protect the underlying chip against (dirt) particles and corrosion. In the case of a chemical sensor (gas sensor) that detects the presence of a specific gaseous substance (for example carbon monoxide), the cavity must not be covered, of course. Suitable soft potting compounds differ significantly from the mold compound (for example) that is used for the fabrication of the chip package and cures completely (whereas the soft potting compounds such as silicone gel remain soft).

The production of the sensor device 1 is relatively complex and costly; particularly the chip-to-chip bonding (after production of the chip package) and the separate wire bonding of the sensor chip increase the overall costs of the sensor device. The example implementation shown in FIG. 2, as will be explained below, can be produced more simply and more efficiently. In this case, unlike in the previous example, the mounting of the sensor chip 20 onto the underlying semiconductor chip 10 does not take place at the end of the production process (after the molding process for producing the package), but rather already much earlier even before the singulation of the wafer into a multiplicity of semiconductor chips 10 using chip-to-wafer bonding. Before the production process is discussed in more specific detail, the resulting sensor device 2 is described below with reference to FIG. 2.

In accordance with FIG. 2, the sensor device 2 comprises a semiconductor chip 10 with a sensor chip 20 mounted thereon. The underside of the sensor chip 20 can be connected to the surface of the chip 10 over the whole area (for example using adhesive bonding, soldering or the like). The top side of the sensor chip 20—unlike in the previous example—is not electrically connected to the underlying chip 10 by bond wires but rather using conductor tracks 23, which also extend across the edge and the narrow side of the sensor chip 20. The conductor tracks 23—also referred to as striplines—can be produced using a printing method or electrochemical deposition (electroplating). Suitable methods for the production of striplines on various surfaces are known per se and, therefore, will not be described further here. As mentioned, the mounting of the sensor chip 20 and the production of the striplines 23 can be carried out at the wafer level, that is to say as long as the wafer is still in one piece and before the wafer is singulated into a multiplicity of semiconductor chips 10. After mounting and production of the striplines 23, the latter and optionally also parts of the sensor chip 20 (or the entire sensor chip) can be covered by a protective layer 24.

For example, a gel can be applied as protective layer 24 (gel casting). However, other protective layers for protection against particles or other harmful environmental influences are also known. The sensitive part of the sensor element can be omitted from the protective layer 24, depending on the application.

After singulation, the semiconductor chips 10 together with the sensor chips 20 mounted thereon are mounted on a leadframe 30. The chip 10 is electrically connected to the chip contacts (for example pins, solder balls, etc.) of the leadframe 30 using bond wires 12 in a conventional manner. Afterward, the chip 10 including bond wires 12 and also parts of the striplines are encapsulated with a potting compound 31 (mold compound) that forms the chip package. In this case, too, the package 31 has an opening/cavity in order that the sensor element 21 at the surface of the sensor chip 20 can interact with the medium surrounding the device. In this example, too, the package 31 can be produced by a FAM process known per se.

By omitting the bond wires (denoted in FIG. 1 by 22), the integrated sensor can be of a more compact structure. The opening can be smaller relative to the sensor chip 20 and the distance between the sensor chip 22 and the mold compound 31 can be very small, that is to say the mold compound 31 can expand up to the lateral edge of the sensor chip 20. Even in the vertical direction, the chip package can be dimensioned to be more compact, as the striplines require significantly less space than the loops of the bond wires.

In comparison with the first example from FIG. 1, no soft potting compound such as for example silicone is necessary to protect bond wires in the example from FIG. 2. Instead, the dielectric protective layer 24 protects the striplines 23, which can be applied to the wafer even before the chips are singulated (for example using photolithographically produced masks).

The replacement of the bond wires by the striplines 23 and the replacement of the soft potting compound by the (much harder) dielectric protective layer 24 also result in adverse effects, which at first glance make the suitability of the concept shown in FIG. 2 for the production of integrated sensors questionable (if not impossible). As a result of the processes (for example applying the layer 24, singulating the chips, molding process, etc.) carried out after mounting the sensor chips 20 on the wafer, residual stresses are introduced into the sensor chip 20, which negatively affect the performance of the sensor chip 20. This is especially true for MEMS sensors. Furthermore, in the example according to FIG. 2, the sensor chip 20 (using a standard process for chip-on-chip mounting) can be fixedly mounted on the chip 10 in a conventional manner, whereas in the example of FIG. 1, the sensor chip 20 is mounted with a relatively soft adhesive on the underlying chip 10 to avoid the introduction of the mentioned residual stresses.

In the example from FIG. 1, the low-stress mounting of the sensor chip 20 is ensured by the soft adhesive 12, the use of flexible bond wires and the embedding of the sensor chip in relatively soft silicone. In order to make the alternative approach according to FIG. 2 at all practicable for sensors, stress relief at the chip or wafer level is provided. This is shown in the detailed drawing denoted by “X” in FIG. 2. In this detailed drawing, it can be seen that the sensor element 21 contained in the sensor chip 20 is enclosed by so-called trenches 25. These trenches 25 cause large-scale mechanical decoupling of (for example MEMS) sensor element 21 and the rest of the sensor chip 20.

The stress-decoupling trenches 25 only allow the expedient use of the striplines 23 for contacting the sensor chip 21, the use of a standard process for chip-on-chip mounting, and the omission of the soft potting compound 32. By exposing the MEMS membrane directly to the environment (without a layer of silicone/gel/soft potting compound), the overall performance of the sensor is improved. This is possible because corrosion resistance is ensured by the use of striplines that are protected by the dielectric layer 24. The exposure of the membrane is easily achieved by the FAM molding process. A larger opening in the chip package as in the example from FIG. 1 is not necessary.

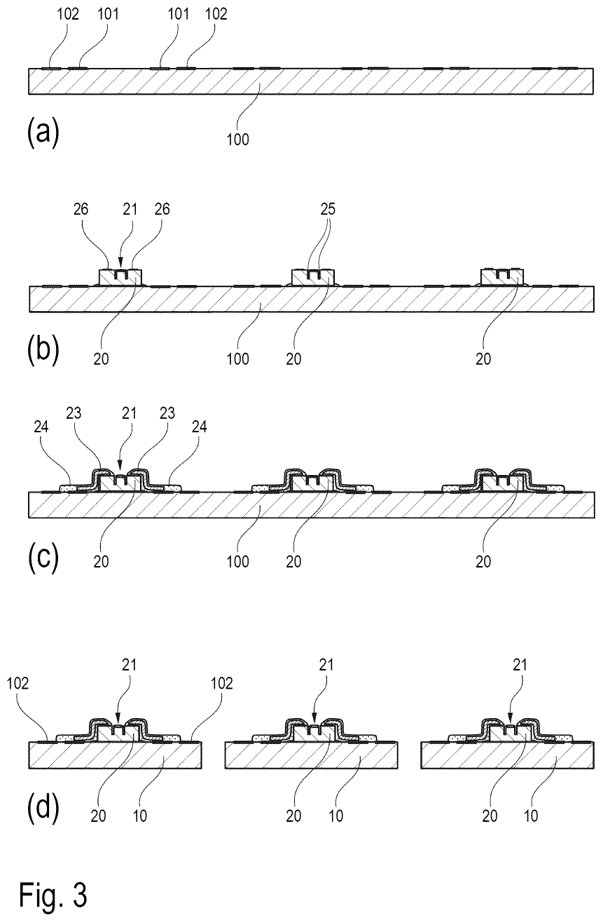

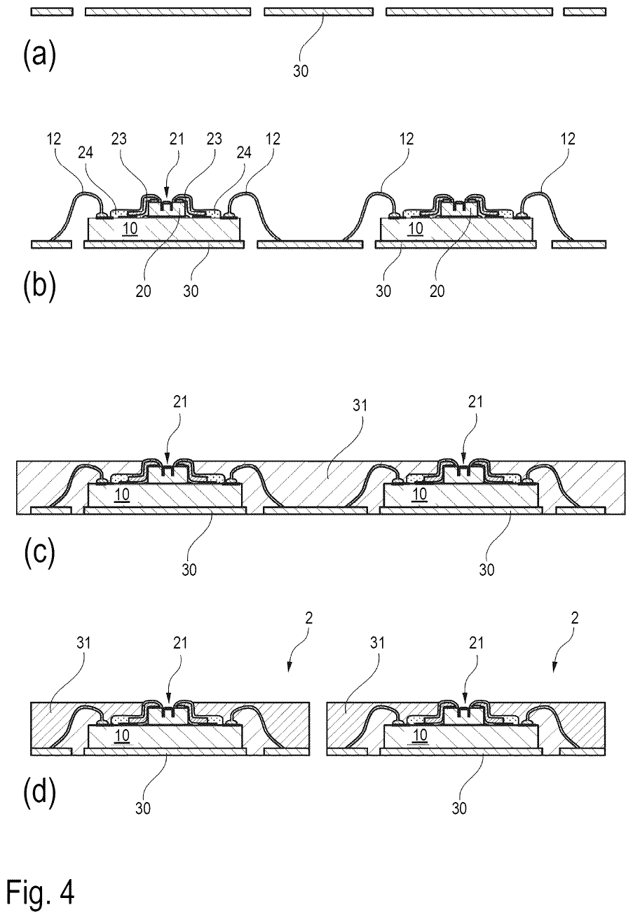

FIG. 3 illustrates, in the diagrams (a) to (d), various intermediate steps in the production of the chip-on-chip arrangement from FIG. 2. The diagram (a) in FIG. 3 shows a wafer 100 having a plurality of semiconductor chips 10 (before singulation). The semiconductor chips each have contact pads 101 for connecting the respective chip 10 to a sensor chip 20 and also contact pads 102 for connecting the respective chip 10 to a leadframe (see FIG. 4). The semiconductor chips 10 can be for example application specific integrated circuits (ASICs) configured specifically for use with a specific sensor chip. By way of example, the semiconductor chips can contain digital electronics for processing the sensor signals supplied by the respective sensor chips 20 and for digital communication with other circuits, control units, or the like. The semiconductor chip 10 (in conjunction with the sensor chip 20) can be considered as a system-on-chip.

In a next step, a plurality of sensor chips 20 are bonded onto the corresponding semiconductor chips 10 of the wafer 100. Suitable chip-to-wafer bonding techniques (also referred to as die bonding) are known per se. By way of example, the sensor chips 20 (dies) can be bonded onto the underlying semiconductor chip using adhesive bonding, soldering or thermosonic bonding. The result of the die bonding process is illustrated in diagram (b) in FIG. 3. Furthermore, diagram (b) of FIG. 3 illustrates contact pads 26 on the top side of the sensor chip 21 (alongside the sensor element 21). In the next step, these contact pads 26 are electrically connected to the corresponding contact pads 101 of the semiconductor chip 10. The above-mentioned stress-decoupling trenches 25 next to the sensor element 21 (MEMS) of the sensor chips 20 are also shown.

The diagram (c) in FIG. 3 shows the wafer with the sensor chips 20 arranged thereon after the production of conductor tracks 23 (striplines) in order to contact the sensor chips 20 with the corresponding semiconductor chips 10 of the wafer 100, wherein the striplines 23 run over the edges of the sensor chips 20. In the example illustrated, the striplines 23 run from a contact pad 26 over the edge of the respective sensor chip 20 (and thus also over the adjoining narrow side of the sensor chip) as far as a corresponding contact pad 101 of the underlying semiconductor chip 10.

After the production of the striplines 23, the latter can be covered with a dielectric protective layer 24 in order to protect the striplines 23 against harmful influences of the environment. A dielectric layer can also be arranged between the sensor chip 20 and the striplines 23 (except in the region of the contact pads 26) in order to avoid undesired short circuits. Various suitable materials for the production of the dielectric layer 24 are known (for example polyimides, photoresist, other structured polymers, etc.). The diagram (d) in FIG. 3 shows the semiconductor chips 10 with sensor chips 20 mounted thereon after the singulation of the wafer 100.

FIG. 4 illustrates, in the diagrams (a) to (d), various intermediate steps of the packaging process of the chip-on-chip arrangement from FIG. 3. In a first step, a chip carrier 30 is provided (see diagram (a) of FIG. 4). The chip carrier can be a leadframe, a printed circuit board (PCB), a multilayer substrate or some other suitable carrier material. In the example implementations illustrated, a leadframe is used as chip carrier 30.

The chip-on-chip systems, each comprising a semiconductor chip 10 and the sensor chip 20 mounted thereon, are mounted onto the chip carrier/leadframe 30. Suitable die bonding techniques are known per se for this purpose (for example soldering, adhesive bonding) and, therefore, will not be discussed further here. The semiconductor chips 10 (that is to say their contact pads 102, see diagram (d) of FIG. 3) are electrically connected to the associated chip contacts (for example pins, solder balls, etc.) of the leadframe 30 using bond wires 12. A conventional wire bonding process can be used for this purpose. The intermediate result is illustrated in diagram (b) of FIG. 4.

In the next step, the result of which is illustrated in diagram (c) of FIG. 4, the chip package (also referred to as encapsulation) is produced from potting compound 31. A suitable process is known, for example, as film-assisted molding (FAM). In this case, a region around the sensor element 21 (that is to say the active sensor area) at the top side of the sensor chip 20 is left free, such that the chip package 31 has an opening and the medium surrounding the sensor device 2 can interact with the sensor element 21. In contrast to the example from FIG. 1, the cavity (the opening in the chip package 21) does not extend to the semiconductor chip 10. The surface of the semiconductor chip 10 is not exposed, but is covered with potting compound 31. The potting compound 21 extends to the edge of the sensor chip 20 or the layer 24 that is arranged thereon and protects the striplines 23.

A soft potting compound as in the example of FIG. 1 for covering the sensor element 21 can be used, but—unlike in the example from FIG. 1—is not necessary, since the striplines 23 are already protected by the dielectric layer 24 (for example a polyimide).

In the example illustrated, the leadframe 30 is fashioned such that it can accommodate a plurality of chips in order to produce a multiplicity of sensor devices in one step. After the molding process for the production of the chip package, the individual sensor devices 2 are singulated. The result is illustrated in diagram (d) of FIG. 4.

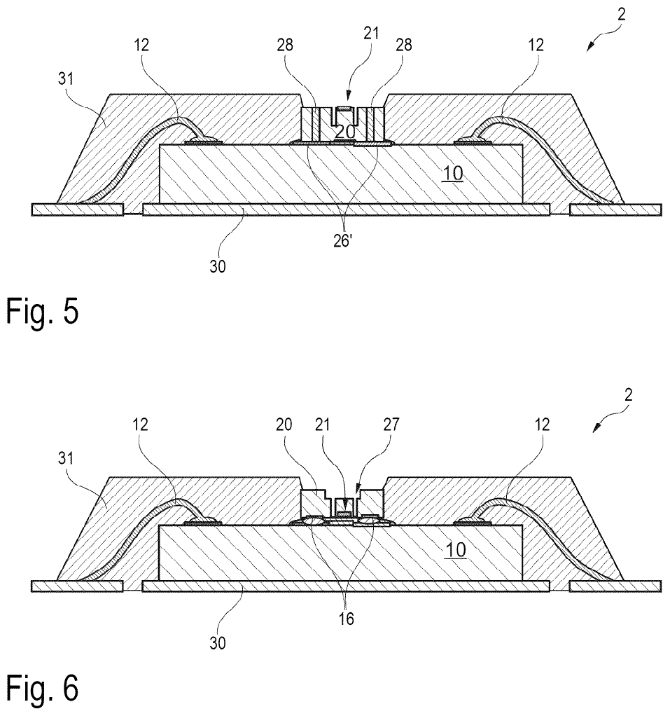

FIGS. 5 and 6 illustrate two alternative example implementations to the example from FIG. 2. The two example implementations differ from the previous examples substantially only in the way in which the sensor chip 20 is mounted on the underlying semiconductor chip 10 and the way in which the two chips 10, 20 are electrically connected.

In the example from FIG. 5, the sensor chip 20 has through contacts 28, so-called through silicon vias (TSV). These serve for electrically connecting the sensor element 21 on the top side of the sensor chip 20 to contact pads 26′ on the underside of the sensor chip 20. The contact pads 26′ are connected to corresponding contact pads of the semiconductor chip 10 during die bonding (that is to say the mounting of the sensor chip 20 onto the underlying chip 10).

As in the previous example, the chip package 31 produced from potting compound has an opening/cavity that makes it possible for the sensor element 21 on the top side of the sensor chip 21 to interact with the medium surrounding the sensor device. As in the previous examples, the package can be produced using FAM, for example. As can be seen in FIG. 5, in this example there is no need for conductor tracks/striplines (cf. FIG. 2, striplines 23) for the contacting of the sensor chip 20. Therefore, in the present example, the opening/cavity in the chip package 31 can be configured to be smaller than in the example from FIG. 2. In the example illustrated, the potting compound 31 extends directly as far as the edge of the sensor chip 20. The sensor device can thus be constructed with a smaller size overall.

The example from FIG. 6 is an alternative design to the example from FIG. 5. In accordance with FIG. 6, the sensor chip 20 is mounted on the underlying semiconductor chip 10 using flip-chip technology. That is to say that the contact pads 26 on the top side of the sensor chip 20 are directly connected to corresponding contact pads of the semiconductor chip 10 (for example using soldering or using electrically conductive adhesive), the sensor chip 20 being mounted on the semiconductor chip 10 with its top side facing the latter (top side downward). In order that the sensor element 21, facing the semiconductor chip 10 on account of the flip-chip mounting in the present example, can interact with the surrounding medium, in the sensor chip 20 provision is made of one or more openings 27 running through the sensor chip 20 or at least as far as the sensor element 21, through which openings the medium can advance as far as the sensor element 20. Apart from the configuration and mounting technique of the sensor chip 20, the example from FIG. 6 is the same as the previous example from FIG. 5. In both examples (FIGS. 5 and 6), the opening in the chip package may be configured to be very small, that is to say the mold compound 31 that forms the chip package extends to the edge of the sensor chip 20 or even overlaps the edge (the contour) of the sensor chip 20.

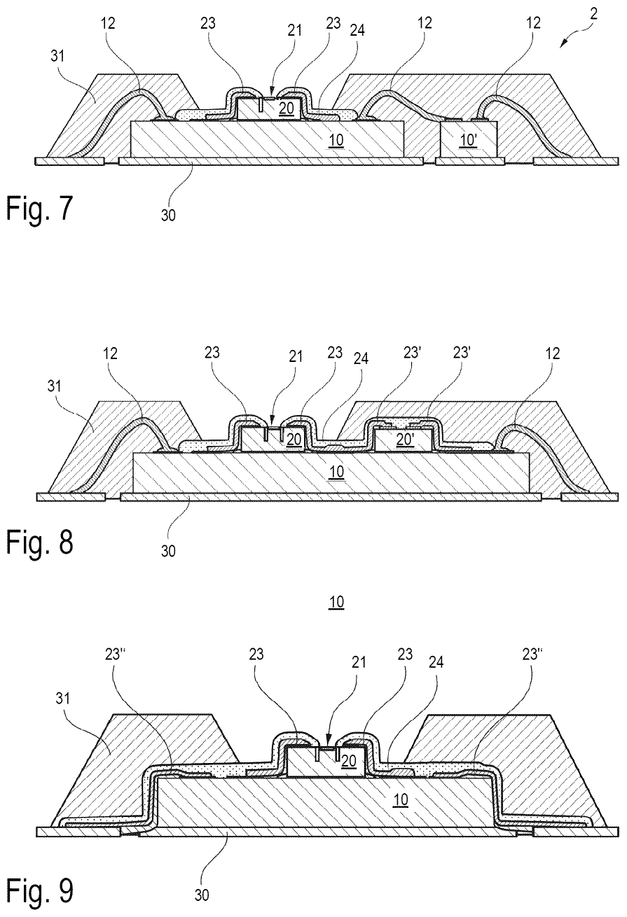

FIGS. 7-9 show further alternative example implementations. The example from FIG. 7 is essentially the same as the example from FIG. 2 apart from the fact that an additional semiconductor chip 10′ is arranged on the leadframe 30 next to the semiconductor chip 10. The additional semiconductor chip 10′ is connected to chip contacts (pins, solder balls) of the leadframe 30 and to the semiconductor chip 10 using bond wires 12. The additional semiconductor chip 10′ and all of the bond wires 12 are completely encapsulated by the potting compound 31. In addition, what has been described above with reference to FIG. 2 applies.

The example from FIG. 8 is also essentially the same as the example from FIG. 2 apart from the fact that an additional chip 20′ is arranged on the semiconductor 10 next to the sensor chip 20. In the example illustrated, the chip 20′ is mounted on the underlying chip 10 in the same manner as the sensor chip 20. The electrical contacting of the chip 20′ is also carried out, as with the sensor chip 20, using striplines 23′ that extend beyond the edge of the chip 20′. The conductor tracks/striplines 23 and 23′ are covered by a dielectric protective layer 24, as shown in FIG. 2. The additional chip 20′ is not a sensor chip and can therefore be completely encapsulated by the potting compound 31. As an alternative, the additional chip 20′ can also be in the form of a sensor chip. In this case, the potting compound (the package) would have an additional cavity. In another example implementation, the additional chip 20 is connected to the underlying chip 10 using flip-chip technology or by way of through-silicon vias.

The example from FIG. 9 illustrates an additional modification of the example from FIG. 2. The only difference from the previous example from FIG. 2 is that the semiconductor chip 10 is electrically connected to corresponding chip contacts of the leadframe 30 not via bond wires 12, but via conductor tracks/striplines 23′″. The conductor tracks 23′″ (as well as the striplines 23 and 23′) can also be produced using a printing method or electrochemical deposition (electroplating). Such methods are suitable for producing striplines on three-dimensional structures (and thus beyond chip edges).

In the examples from FIGS. 2-9, the sensor chips 20 (and optionally additional chips 20′) are bonded to the wafer, even before it is divided into individual chips. This is made possible by the fact that wire bonding techniques are also omitted in order to electrically contact the sensor chips 20. The omission of bond wires also allows for significantly smaller dimensioning of the opening/cavity in the chip package. As shown in FIGS. 2, 5 and 6, the mold compound 31 that forms the chip package can reach to the edge of the sensor chip 20 or even overlap the chip edge. The striplines can (unlike bond wires) be protected by a relatively hard dielectric layer 24 (for example polyimide) and a soft potting compound such as for example a silicone gel is not necessary, which can further improve the performance of the sensor chip. The mold compound 31 does not have to or does not significantly have to exceed the top side of the sensor chip (for example the dielectric layer), that is to say the cavity can (unlike in the example from FIG. 1) be of a relatively flat design. Additional protection of the sensor element 21 by a soft potting compound is an option, but no longer absolutely necessary.

However, in the case of MEMS sensors, in particular pressure sensors, the concepts described here (in particular the encapsulation of the semiconductor chip after the chip-on-chip mounting of the sensor chip) can only be expediently used if the residual stresses arising in the sensor chip are decoupled from the sensor element integrated therein (the MEMS). According to the examples described here (FIGS. 2-9), this is achieved using trenches (see FIGS. 2 and 3, trenches 35), which surround the sensor element and which enable mechanical decoupling between the sensor element (MEMS) and the surrounding silicon.

1. A sensor device comprising:
a chip carrier;
a semiconductor chip mounted on the chip carrier;
electrical connections between connection pads of the semiconductor chip and corresponding connection pads of the chip carrier;
a sensor chip arranged on a first portion of the semiconductor chip and having a sensor element:, and
a mold compound that forms a chip package, at least partially encapsulates the semiconductor chip and the electrical connections and has an opening in a region of the sensor element so that the sensor element can interact with a medium surrounding the sensor device,
wherein the mold compound covers the semiconductor chip except for the sensor chip, and
wherein the sensor chip has trenches that mechanically decouple the sensor element from a second portion of the sensor chip.

2. The sensor device as claimed in claim 1, wherein the semiconductor chip and the sensor chip have corresponding contact pads that are connected using conductor tracks that run over an edge of the sensor chip.

3. The sensor device as claimed in claim 2, wherein the conductor tracks are produced using electrochemical deposition or using a printing method.

4. The sensor device as claimed in claim 2, wherein the mold compound at least partially covers the conductor tracks.

5. The sensor device as claimed in claim 2, wherein the conductor tracks are covered by a dielectric layer.

6. The sensor device as claimed in claim 1, wherein the sensor chip is mounted on the semiconductor chip using flip-chip technology so that the sensor element is facing the semiconductor chip, and
wherein the sensor chip has an opening that establishes a connection between the sensor element and an environment.

7. The sensor device as claimed in claim 2, wherein the sensor element is arranged on a top side of the sensor chip, and
wherein all of the corresponding contact pads of the sensor chip that are connected to the semiconductor chip are arranged on an underside of the sensor chip.

8. The sensor device as claimed in claim 7, wherein the sensor chip has vias that extend through the sensor chip and that electrically connect the sensor chip to the semiconductor chip.

9. The sensor device as claimed in claim 1, wherein the electrical connections between the connection pads of the semiconductor chip and corresponding connection pads of the chip carrier are formed by bond wires.

10. The sensor device as claimed in claim 1, wherein at least one of:
the mold compound has an opening with a contour that is aligned approximately with the contour of the sensor chip, or
side surfaces of the sensor chip are in physical contact with the mold compound.

11. The sensor device as claimed in claim 1, wherein the sensor element is a microelectromechanical system (MEMS).

12. A method comprising:
providing a wafer having a plurality of semiconductor chips;
bonding a plurality of sensor chips on corresponding semiconductor chips, wherein the sensor chips each have a sensor element and trenches that mechanically decouple the sensor element from a portion of the sensor chip;
singulating the semiconductor chips with the sensor chips arranged thereon;
mounting the semiconductor chips on corresponding chip carriers; and
encapsulating the semiconductor chip with a mold compound, wherein an opening is left free in the mold compound in a region of a sensor element of the sensor chip.

13. The method as claimed in claim 12, further comprising:
prior to singulating the semiconductor chips:
producing conductor tracks configured to contact the sensor chips with the corresponding semiconductor chips, wherein the conductor tracks run over an edge of the sensor chips.

14. The method as claimed in claim 13, wherein the conductor tracks are produced using electrochemical deposition.

15. The method as claimed in claim 13, wherein the conductor tracks are produced using a printing method.

16. The method as claimed in claim 13, wherein the mold compound at least partially covers the conductor tracks.

17. The method as claimed in claim 13, wherein the conductor tracks are covered by a dielectric layer.

18. The method as claimed in claim 12, wherein the sensor chips are bonded to the corresponding semiconductor chips to cause the sensor element to face the corresponding semiconductor chips.

19. The method as claimed in claim 12, wherein side surfaces of the sensor chips are in physical contact with the mold compound.

20. The method as claimed in claim 12, wherein the sensor element of the sensor chips comprise a micro electromechanical system (MEMS).
